(19) United States
(12) Patent Application Publication
(10) Pub. No.: US 2023/0162952 A1
(43) Pub. Date: May 25, 2023

(54) EDGE RING FOR SEMICONDUCTOR MANUFACTURING PROCESS WITH DENSE BORON CARBIDE LAYER ADVANTAGEOUS FOR MINIMIZING PARTICLE GENERATION, AND THE MANUFACTURING METHOD FOR THE SAME

(71) Applicant: BCnC Co., Ltd., Icheon-si (KR)

(72) Inventor: Changwook SEOL, Pyeongtaek-si (KR)

(21) Appl. No.: 17/895,822

(22) Filed: Aug. 25, 2022

(30) Foreign Application Priority Data
Nov. 25, 2021 (KR) 10-2021-0164456

(51) Int. Cl. H01J 37/32; H01L 21/687; C23C 16/32; C23C 16/02

(52) U.S. Cl. CPC H01J 37/32642; H01L 21/68721; C23C 16/32; C23C 16/0272; H01J 2237/3343

(57) ABSTRACT

Proposed is an edge ring for a semiconductor manufacturing process, and specifically, to an edge ring for a semiconductor manufacturing process, which has a denser surface structure by forming a denser boron carbide surface layer on the surface of a sintered body (base layer) formed of boron carbide powder and forming a mixed layer for preventing peeling between the base layer and the surface layer and improving physical properties therebetween, and thus the boron carbide sintered body is prevented from being cracked during a harsh plasma process, and particle generation caused by the cracking is effectively suppressed, and as a result, a defective product rate can be reduced, and a manufacturing method thereof.

### CROSS-REFERENCE TO RELATED APPLICATION

This application claims priority to and the benefit of Korean Patent Application No. 10-2021-0164456 filed on Nov. 25, 2021, the disclosure of which is incorporated herein by reference in its entirety.

### BACKGROUND

### 1. Field of the Invention

The present invention relates to a dense boron carbide-based edge ring for a semiconductor manufacturing process, which is advantageous for minimizing particle generation, and a manufacturing method thereof.

### 2. Discussion of Related Art

This achievement (or publication) is a research support project for self-reliance of material/parts/equipment industry, which is conducted with the support of the Advanced Convergence Technology Institute and the financial resources of Gyeonggi-do in 2021 (No. AICT-E1-030(AICT-009-T1)).

In general, a plasma processing technique used in a semiconductor manufacturing process is one of the dry etching processes and is a method of etching an object using gases. This follows a process in which an etching gas is injected into a reaction container, ionized, and then accelerated to a wafer surface to physically and chemically remove the wafer surface. The method is widely used because etching is easily adjusted, productivity is high, and the formation of fine patterns of several tens of nanometers is possible.

As an example, a plasma device (chamber) in which plasma etching is performed consists of an upper electrode, an electrostatic chuck including an electrode at the lower portion of the device, and a covering assembly surrounding the electrostatic chuck so that the electrostatic chuck is protected from plasma generated in the plasma processing chamber, and a substrate such as a semiconductor wafer or a glass substrate is supported by the upper surface of the electrostatic chuck.

When a power source is applied between the upper electrode and the electrostatic chuck, plasma (P) is generated in the plasma processing chamber due to the electric field effect, and thus ions are incident toward the electrostatic chuck, and etching is performed on the substrate by the chemical reaction and kinetic energy of plasma ions.

Meanwhile, the covering assembly surrounding the electrostatic chuck may have a configuration in which a coupling groove is formed in the lower surface of an edge ring and an electrode ring is coupled thereto, and the edge ring (also referred to as a focus ring) is configured to surround the side of the substrate supported by the upper surface of the electrostatic chuck and is a ceramic part for manufacturing a semiconductor, which is manufactured in a three-dimensional shape in accordance with a standard and environment capable of maintaining the same height as that of the substrate supported by the electrostatic chuck.

Meanwhile, conventional edge rings are manufactured using single-crystal and columnar silicon, quartz (SiO₂), or chemical-vapor-deposited silicon carbide (CVD SiC). However, since this composition is excessively etched under harsh plasma conditions, there is a problem in that maintenance or frequent replacement with new parts is required after a short period of use. Also, when expensive materials such as yttria (Y₂O₃) and sapphire are used for the edge rings, there is a problem in economic feasibility.

Meanwhile, as the power of the plasma process increases by decreasing the line width of semiconductors and increasing the number of stacks, process conditions are currently being changed, and conventionally widely used boron carbide has reached a limitation in plasma resistance. Particularly, boron carbide including pores in a sintered body has a problem in that particles are generated during a plasma process to cause defective products, and accordingly, studies on a method for preventing this are being actively conducted.

### SUMMARY OF THE INVENTION

The present invention has been devised to address the problems of a conventional edge ring which is a ceramic part used in a semiconductor manufacturing process and is directed to providing an edge ring for a semiconductor manufacturing process, which ensures a dense surface by forming a mixed layer on the surface of a base layer, which is formed of boron carbide powder and has a low density, by chemical vapor deposition (CVD) and forming a denser surface layer on the surface of the mixed layer by CVD, and effectively prevents peeling between the base layer and the surface layer, and thus particle generation is effectively suppressed, and as a result, a defective product rate can be reduced, and a manufacturing method thereof.

However, technical problems to be solved by the present invention are not limited to the technical problems described above, and other technical problems not disclosed herein will be clearly understood from the following description by those skilled in the art.

One aspect of the present invention provides an edge ring for a semiconductor manufacturing process, which includes: a boron carbide (B₄C) base layer; a mixed layer formed on the surface of the boron carbide base layer; and a boron carbide (B₄C) surface layer formed on the surface of the mixed layer.

In an embodiment, the base layer may have a density of 1.0 to 1.9 g/cc, the mixed layer may have a density of 1.8 to 2.3 g/cc, and the surface layer may have a density of 2.1 to 2.52 g/cc. In an embodiment, the mixed layer may have a thickness of 0.1 to 5 mm, the surface layer may have a thickness of 1 to 10 mm, and the sum of the thicknesses of the base layer, mixed layer, and surface layer may range from 3 to 20 mm.

In an embodiment, the mixed layer may have a density gradient in which the density of the mixed layer converges to the numerical range of the density of the base layer by relatively lowering the density of the mixed layer as it is closer to the base layer and converges to the numerical range of the density of the surface layer by relatively increasing the density of the mixed layer as it is closer to the surface layer.

Another aspect of the present invention provides a method of manufacturing an edge ring for a semiconductor manufacturing process, which includes the steps of: a) forming a base layer using boron carbide (B₄C) powder; b) forming a mixed layer on the surface of the base layer by a CVD process; and c) after the formation of the mixed layer, forming a surface layer on the surface of the mixed layer by a CVD process, wherein the step a) of forming a base layer is performed by one or more methods selected from 1) sintering after cold isostatic pressing (CIP), 2) sintering after hot isostatic pressing (HIP), and 3) hot pressing.

In an embodiment, in the step a) of forming a base layer, sintering temperature and process pressure conditions may be adjusted to control at least one physical property of the resistance, density, and permittivity of an edge ring,

In an embodiment, the step b) of forming a mixed layer may be performed in a temperature range of 900 to 1,400° C. and a pressure range of 5 to 400 Torr.

In an embodiment, the step c) of forming a surface layer may be performed in a temperature range of 1,000 to 1,600° C. and a pressure range of 50 to 750 Torr.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows an exemplary structure of a general plasma device (chamber); and

FIG. 2 shows a schematic cross-sectional view of a boron carbide-based edge ring for a semiconductor manufacturing process according to an embodiment of the present invention.

### DETAILED DESCRIPTION OF EXEMPLARY EMBODIMENTS

Hereinafter, exemplary embodiments of the present invention will be described in detail with reference to the accompanying drawings. However, in describing the present description, descriptions of already known functions or configurations will be omitted to clarify the gist of the present description.

Hereinafter, an edge ring for a semiconductor manufacturing process, whose resistance is able to be adjusted, according to a specific embodiment of the present invention will be described in detail.

Edge Ring for Semiconductor Manufacturing Process

As described above, an edge ring for a semiconductor manufacturing process according to an embodiment of the present invention includes: a boron carbide (B₄C) base layer; a mixed layer formed on the surface of the boron carbide base layer; and a boron carbide (B₄C) surface layer formed on the surface of the mixed layer.

Specifically, in the case of a semiconductor wafer manufacturing process, a decrease in line width and an increase in the number of stacks are currently becoming a big issue, and a ceramic part for semiconductor manufacturing used in the process needs to withstand harsher plasma conditions. As a part for semiconductor manufacturing, an edge ring (or focus ring) is generally manufactured using silicon (Si), quartz (SiO₂), or chemical-vapor-deposited silicon carbide (CVD SiC) and has a problem in that maintenance or replacement with a new part is required after a short period of use by being excessively etched under harsh plasma conditions. This results in reducing the production of semiconductor products and increasing a defective product rate.

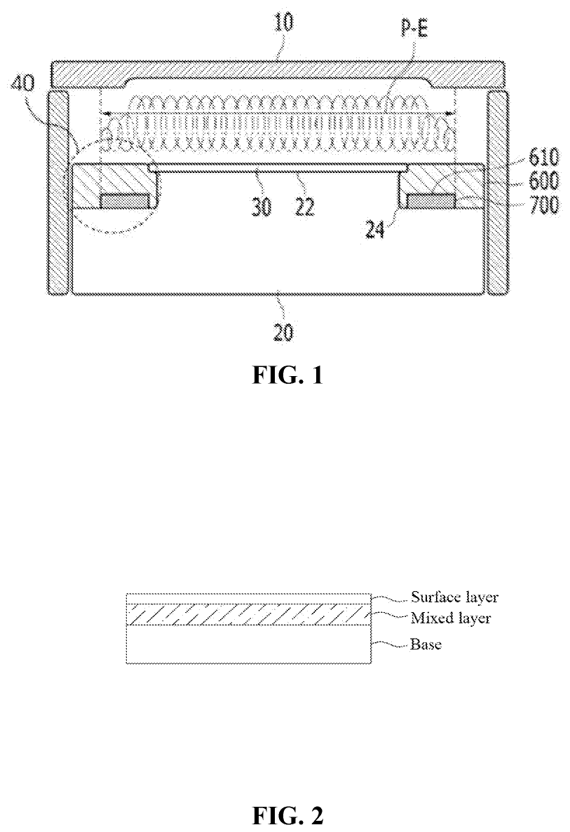

First, FIG. 1 relates to a plasma device to which an edge ring for a semiconductor manufacturing process according to an embodiment of the present invention is applied. Specifically, the plasma device (chamber) consists of an upper electrode 10, an electrostatic chuck 20 including an electrode at the lower portion of the device, and a covering assembly 40 surrounding the electrostatic chuck 20 so that the electrostatic chuck 20 is protected from plasma generated in the plasma processing chamber, and a substrate 30 such as a semiconductor wafer or a glass substrate may be supported by the upper surface of the electrostatic chuck 20.

As described above, a device for etching a semiconductor substrate using a reactive gas in a plasma state by applying a RF power source has already been disclosed in several related-art documents such as U.S. Pat. No. 5,259,922 and the like. Therefore, in this specification, even if the operating principle of a plasma processing chamber is not described in detail, those skilled in the art will be able to easily understand it through the structure of a general plasma processing chamber to which the present invention is applied.

Meanwhile, the covering assembly 40 in the plasma processing chamber is disposed on an annular step 24 of the electrostatic chuck 20 so that it surrounds the electrostatic chuck 20 and is basically manufactured using an electrically non-insulating material to serve to protect the electrostatic chuck 20 from a plasma reaction (P-E) in the plasma processing chamber.

The covering assembly may include an edge ring 600 and an electrode ring 700. The edge ring is disposed on the annular step 24 of the electrostatic chuck 20 so that it surrounds the side of the electrostatic chuck 20 and may have a three-dimensional annular shape. Meanwhile, the edge ring may be configured to surround the side of the substrate 30 supported by the upper surface 22 of the electrostatic chuck 20, and in this case, the edge ring may be manufactured in accordance with a standard capable of maintaining the same height as that of the substrate 30 supported by the electrostatic chuck 20. Meanwhile, the edge ring, which is one of the components of the covering assembly, may be generally made of quartz or boron carbide (B₄C) as described above.

Meanwhile, when the edge ring is made of quartz or boron carbide as described above, wear and frequent replacement accompany continuous exposure to harsh plasma conditions. This is a major cause of increasing the manufacturing cost of semiconductor products and degrading marketability. Therefore, to reduce the frequency of replacement of parts, such as the edge ring, made of quartz, boron carbide, or silicon carbide (SiC), various studies for improving plasma resistance are in progress.

Based on the above problems, the inventors of the present invention have found that, when a denser boron carbide surface layer is formed on the surface of a sintered body (base layer) made of boron carbide (B₄C) powder, and a mixed layer for preventing peeling between the base layer and the surface layer and improving physical properties is formed therebetween in the manufacture of an edge ring for a semiconductor manufacturing process, a dense boron carbide-based edge ring for a semiconductor, which is advantageous for minimizing particle generation, can be manufactured, and when sintering temperature and process pressure conditions are adjusted in the formation of the base layer, the resistance, density, and permittivity of an edge ring can be controlled to desired levels, and thus uniform plasma can be formed on the entire wafer surface, and the edge ring with this configuration reduces a defective product rate by preventing cracking of the boron carbide sintered body and effectively suppressing particle generation caused by the cracking, and completed the present invention.

First, boron carbide (B₄C) is used as a main material of the edge ring for a semiconductor manufacturing process according to the present invention and generally has a thermal conductivity of 29 to 67 W/m·K and an electrical resistance of 0.1 to 10 Ω·cm. Meanwhile, according to an embodiment of the present invention, to suppress particle generation caused by surface cracking during a plasma process using the finally manufactured edge ring for a semiconductor manufacturing process, the edge ring is configured with a multi-layer structure including a boron carbide-based mixed layer and surface layer having different densities on the surface of the boron carbide sintered body (base layer).

Specifically, a mixed layer formed by chemical vapor deposition (CVD) may be provided on the surface of the base layer which is a boron carbide sintered body, and a surface layer may be provided on the surface of the mixed layer.

According to an embodiment of the present invention, the base layer may have a density of 1.0 to 1.9 g/cc, the mixed layer may have a density of 1.8 to 2.3 g/cc, and the surface layer may have a density of 2.1 to 2.52 g/cc. As described above, when the density of the surface layer is relatively higher than the density of the base layer, surface cracking can be effectively suppressed during a harsh plasma process.

Meanwhile, the mixed layer may be provided to prevent peeling between the base layer and the surface layer and simultaneously improve physical properties. As an example, the mixed layer may have a thickness of 0.1 to 5 mm, the surface layer may have a thickness of 1 to 10 mm, and the sum of the thicknesses of the base layer, mixed layer, and surface layer may range from 3 to 20 mm.

Meanwhile, the mixed layer may have a density gradient in which the density of the mixed layer converges to the numerical range of the density of the base layer by relatively lowering the density of the mixed layer as it is closer to the base layer and converges to the numerical range of the density of the surface layer by relatively increasing the density of the mixed layer as it is closer to the surface layer, and the gradient may include a linear or exponential increase or decrease.

Meanwhile, the edge ring for a semiconductor manufacturing process according to an embodiment of the present invention may make it possible to form a precise hole in formation of a via hole by uniformizing the directionality of plasma. Also, as described above, the edge ring for a semiconductor manufacturing process according to the present invention may reduce the occurrence of arcing to minimize defective chips caused by the arcing.

Manufacturing Method of Edge Ring for Semiconductor Manufacturing Process

A method of manufacturing the above-described edge ring for a semiconductor manufacturing process according to an embodiment of the present invention includes the steps of: a) forming a base layer using boron carbide (B₄C) powder; b) forming a mixed layer on the surface of the base layer by a CVD process; and c) after the formation of the mixed layer, forming a surface layer on the surface of the mixed layer by a CVD process, wherein the step a) of forming a base layer is performed by one or more methods selected from 1) sintering after cold isostatic pressing (CIP), 2) sintering after hot isostatic pressing (HIP), and 3) hot pressing.

First, a base layer is formed using boron carbide (B₄C) powder (step a).

As an example, the step a) may be performed using boron carbide powder, which is a main material, by one or more methods selected from 1) sintering after cold isostatic pressing (CIP), 2) sintering after hot isostatic pressing (HIP), and 3) hot pressing.

Meanwhile, when a sintering process is performed in the formation of a base layer, sintering may be performed by applying a pressure of 25 MPa to 35 MPa at a temperature ranging from 1,950 to 2,050° C. in a mold.

Meanwhile, according to an embodiment of the present invention, in this step, a sintering temperature may be adjusted to control at least one physical property of resistance, density, and permittivity of an edge ring within a desired range.

Next, a mixed layer is formed on the surface of the base layer by a CVD process (step b).

As an example, the step b) of forming a mixed layer may be performed in a temperature range of 900 to 1,400° C. and a pressure range of 5 to 400 Torr, more specifically, in a temperature range of 900 to 1,100° C. and a pressure range of 5 to 100 Torr, and the mixed layer formed by this process effectively prevents peeling between a surface layer to be described below and the above-described base layer.

Next, after the formation of the mixed layer, a surface layer is formed on the surface of the mixed layer by a CVD process (step c).

As an example, the step c) of forming a surface layer may be performed in a temperature range of 1,000 to 1,600° C. and a pressure range of 50 to 750 Torr, and the surface layer formed by this process may allow particle generation to be minimized under harsh plasma conditions due to having a dense structure.

The sintered body manufactured by the series of steps may be subjected to a cutting process, for example, may be cut by wire cutting or the like, to form an edge ring. Meanwhile, this process may be performed using a coring process or a machining tool.

The above-described edge ring for a semiconductor manufacturing process according to an embodiment of the present invention is suitable for fine processing because the resistance, density, and permittivity thereof are easily adjusted during a plasma etching process to form uniform plasma on the entire wafer surface. In addition, the edge ring according to the present invention minimizes particle generation by decreasing a part etching rate and preventing surface uniformization under harsh plasma conditions, and thus a defective product rate is reduced, and the number of times of replacement or maintenance of process equipment is substantially reduced. Additionally, the edge ring according to the present invention can reduce the occurrence of arcing to minimize defective chips caused by the arcing.

### Examples

The present invention can be subjected to various modifications and can have various examples. Thus, it is intended that specific examples are illustrated and described below in detail. However, it should be understood that this is not intended to limit the present invention to specific examples, and the present invention includes all modifications, equivalents, and alternatives which fall within the spirit and technical scope of the present invention.

### Examples and Comparative Examples

Boron carbide powder was prepared according to the following specifications by the above-described method, and whether a surface layer was cracked and peeled off by an etching process was confirmed.

TABLE 1

| Density | Thickness | Thickness | Etching |
|---|---|---|---|
| of base | of mixed | of surface | amount |
| (g/cc) | layer (mm) | layer (mm) | (μm/hr) |
| 1.0 | 1.37 | 1.98 | 12.618 |
| 1.0 | 1.55 | 3.85 | 12.594 |
| 1.9 | 0.32 | 2.22 | 12.912 |
| 1.9 | 0.29 | 4.01 | 12.824 |
| 2.1 | <0.05 | 2.33 | crack + peeling |

Referring to the results of Table 1, it can be confirmed that, as the density of the base was lower, a thicker mixed layer was formed due to the smooth supply of gases in a CVD process, and etching amounts were constant regardless of the density of the base and the thickness of the surface layer. Even when a surface layer was formed directly without a separate process of forming a mixed layer, a mixed layer was formed with a thickness of less than 0.05 mm, but it did not serve to adhere the base and the surface layer, and thus the surface layer was cracked and peeled off during an etching process.

The edge ring for a semiconductor manufacturing process according to the present invention is suitable for fine processing because the resistance, density, and permittivity thereof are easily adjusted during a plasma etching process to form uniform plasma on the entire wafer surface.

In addition, the edge ring according to the present invention minimizes particle generation by decreasing a part etching rate and preventing surface uniformization under harsh plasma conditions, and thus a defective product rate is reduced, and the number of times of replacement or maintenance of process equipment is substantially reduced.

Additionally, the edge ring according to the present invention can reduce the occurrence of arcing to minimize defective chips caused by the arcing.

As described above, specific exemplary embodiments of the present invention have been described, but the present invention is not limited thereto, and it is clear to those skilled in the art that various modifications and alterations may be made without departing from the spirit and scope of the present invention. Therefore, it will be understood that the modified exemplary embodiments are not independent from the technical spirit and point of view of the present invention but included in the scope of the present invention defined by the appended claims.

What is claimed is:

1. An edge ring for a semiconductor manufacturing process, comprising:
a boron carbide (B₄C) base layer;
a mixed layer formed on the surface of the boron carbide base layer; and
a boron carbide (B₄C) surface layer formed on the surface of the mixed layer.

2. The edge ring of claim 1, wherein the base layer has a density of 1.0 to 1.9 g/cc,
the mixed layer has a density of 1.8 to 2.3 g/cc, and
the surface layer has a density of 2.1 to 2.52 g/cc.

3. The edge ring of claim 1, wherein the mixed layer has a thickness of 0.1 to 5 mm,
the surface layer has a thickness of 1 to 10 mm, and
the sum of the thicknesses of the base layer, mixed layer, and surface layer ranges from 3 to 20 mm.

4. The edge ring of claim 1, wherein the mixed layer has a density gradient in which the density of the mixed layer converges to the numerical range of the density of the base layer by relatively lowering the density of the mixed layer as it is closer to the base layer and converges to the numerical range of the density of the surface layer by relatively increasing the density of the mixed layer as it is closer to the surface layer.

5. A method of manufacturing an edge ring for a semiconductor manufacturing process, the method comprising the steps of:
a) forming a base layer using boron carbide (B₄C) powder;
b) forming a mixed layer on the surface of the base layer by a chemical vapor deposition (CVD) process; and
c) after the formation of the mixed layer, forming a surface layer on the surface of the mixed layer by a CVD process,
wherein the step a) of forming a base layer is performed by one or more methods selected from 1) sintering after cold isostatic pressing (CIP), 2) sintering after hot isostatic pressing (HIP), and 3) hot pressing.

6. The method of claim 5, wherein, in the step a) of forming a base layer, sintering temperature and process pressure conditions are adjusted to control at least one physical property of the resistance, density, and permittivity of an edge ring,

7. The method of claim 5, wherein the step b) of forming a mixed layer is performed in a temperature range of 900 to 1,400° C. and a pressure range of 5 to 400 Torr.

8. The method of claim 5, wherein the step c) of forming a surface layer is performed in a temperature range of 1,000 to 1,600° C. and a pressure range of 50 to 750 Torr.
